(19) United States
(12) Patent Application Publication
(10) Pub. No.: US 2025/0069986 A1
(43) Pub. Date: Feb. 27, 2025

(54) SEMICONDUCTOR DEVICE

(71) Applicant: SUMITOMO ELECTRIC INDUSTRIES, LTD., Osaka (JP)

(72) Inventors: So TANAKA, Osaka (JP); Jiro SHINKAI, Osaka (JP)

(21) Appl. No.: 18/719,482

(22) PCT Filed: Dec. 21, 2021
(86) PCT No.: PCT/JP2021/047393

§ 371 Date: Jun. 13, 2024

(51) Int. Cl. H01L 23/373; H01L 23/00; H01L 23/498

(52) U.S. Cl. CPC H01L 23/3735; H01L 23/49833; H01L 24/32; H01L 23/3736; H01L 2224/32225; H01L 2224/32245

(57) ABSTRACT

A semiconductor device includes a semiconductor chip including a semiconductor substrate and a main electrode provided on the semiconductor substrate, a buffer plate, and a bonding material provided between the main electrode and the buffer plate. The main electrode includes an aluminum or aluminum alloy layer. Each of a first coefficient of linear thermal expansion of the semiconductor substrate and a second coefficient of linear thermal expansion of the buffer plate is less than a third coefficient of linear thermal expansion of the main electrode. The second coefficient of linear thermal expansion is less than the first coefficient of linear thermal expansion.

### TECHNICAL FIELD

The present disclosure relates to a semiconductor device.

### BACKGROUND ART

As an example of a semiconductor device suitable for a power module, a semiconductor device has been proposed in which a buffer plate is bonded to an aluminum-containing electrode of a semiconductor chip and a bonding wire is bonded to the buffer plate.

### RELATED-ART DOCUMENTS

### Patent Documents

Patent Document 1: Japanese Unexamined Patent Application Publication No. 2018-186220
Patent Document 2: Japanese Unexamined Patent Application Publication No. 2017-005037
Patent Document 3: Japanese Unexamined Patent Application Publication No. 2019-057663

A semiconductor device according to an embodiment of the present disclosure includes a semiconductor chip including a semiconductor substrate and a main electrode provided on the semiconductor substrate, a buffer plate, and a bonding material provided between the main electrode and the buffer plate. The main electrode includes an aluminum or aluminum alloy layer, each of a first coefficient of linear thermal expansion of the semiconductor substrate and a second coefficient of linear thermal expansion of the buffer plate is less than a third coefficient of linear thermal expansion of the main electrode, and the second coefficient of linear thermal expansion is less than the first coefficient of linear thermal expansion.

### BRIEF DESCRIPTION OF THE DRAWINGS

FIG. 1 is a top view showing a semiconductor device according to a first embodiment.

FIG. 2 is a cross-sectional view showing the semiconductor device according to the first embodiment.

FIG. 3 is a cross-sectional view showing an example of a source electrode.

FIG. 4 is a top view showing the semiconductor device according to a second embodiment.

FIG. 5 is a cross-sectional view showing the semiconductor device according to the second embodiment.

FIG. 6 is a cross-sectional view showing a bonding material between an anode electrode and a buffer plate according to a third embodiment.

FIG. 7 is a cross-sectional view showing the bonding material between the anode electrode and the buffer plate according to a fourth embodiment.

FIG. 8 is a view showing crystal grains that constitute a wire and a second copper layer.

FIG. 9 is a diagram (part 1) showing an example of the result of a power cycling test.

FIG. 10 is a diagram (part 2) showing an example of the result of the power cycling test.

FIG. 11 is a schematic diagram (part 1) showing a change in deformation due to a temperature change.

FIG. 12 is a schematic diagram (part 2) showing the change in deformation due to the temperature change.

FIG. 13 is a schematic diagram (part 3) showing the change in deformation due to the temperature change.

FIG. 14 is a diagram showing a change in a coefficient of linear thermal expansion due to the temperature change.

### MODE FOR CARRYING OUT THE INVENTION

### Problem to be Solved by the Present Disclosure

In a conventional semiconductor device, a failure such as peeling may occur due to internal fracture of a main electrode containing aluminum.

### Effects of the Present Disclosure

In the present disclosure, internal fracture of a main electrode containing aluminum can be suppressed.

Embodiments will be described below.

### Description of Embodiments of the Present Disclosure

First, embodiments of the present disclosure will be listed and described as follows. In the following description, the same or corresponding components are denoted by the same reference numerals, and the same description thereof will not be repeated.

[1] A semiconductor device in one aspect of the present disclosure includes a semiconductor chip including a semiconductor substrate and a main electrode provided on the semiconductor substrate, a buffer plate, and a bonding material provided between the main electrode and the buffer plate. The main electrode includes an aluminum or aluminum alloy layer, each of a first coefficient of linear thermal expansion of the semiconductor substrate and a second coefficient of linear thermal expansion of the buffer plate is less than a third coefficient of linear thermal expansion of the main electrode, and the second coefficient of linear thermal expansion is less than the first coefficient of linear thermal expansion.

Because a third coefficient of linear thermal expansion is greater than a first coefficient of linear thermal expansion, a main electrode tends to thermally deform as compared to a semiconductor substrate. With this arrangement, thermal stress acts on the main electrode. For this reason, as described below, in a power cycling test in which application of a thermal load and non-application of the thermal load are repeated, thermal deformation repeatedly occurs, and the resulting thermal stress causes deterioration of a semiconductor device represented by a power module, which may finally lead to failure. On the other hand, a buffer plate is bonded to the main electrode via a bonding material, and thus thermal deformation of the main electrode can be restrained by a buffer plate. In this case, as described below, because a second coefficient of linear thermal expansion is less than the first coefficient of linear thermal expansion, thermal deformation of the main electrode can be more effectively suppressed by the bonding material. Therefore, thermal stress generated in the main electrode due to thermal deformation can be suppressed, and internal fracture of an aluminum or aluminum alloy layer included in the main electrode can be suppressed.

[2] In [1], the buffer plate has a thickness of greater than or equal to 0.05 mm and less than or equal to 0.25 mm, and when the first coefficient of linear thermal expansion is expressed by ρ1 and the second coefficient of linear thermal expansion is expressed by ρ2, a value defined by “ρ2−ρ1” may be greater than or equal to −2.8×10⁻⁶/° C. and less than or equal to −0.1×10⁻⁶/° C. In this case, thermal stress generated in a main electrode is more easily suppressed.

[3] In [1], the buffer plate has a thickness of greater than or equal to 0.05 mm and less than or equal to 0.25 mm, and when the first coefficient of linear thermal expansion is expressed by ρ1 and the second coefficient of linear thermal expansion is expressed by ρ2, a value defined by “ρ2−ρ1” may be −2.8×10⁻⁶/° C. In this case, thermal stress generated in a main electrode is further easily suppressed.

[4] In [1], the buffer plate has a thickness of greater than or equal to 0.10 mm and less than or equal to 0.20 mm, and when the first coefficient of linear thermal expansion is expressed by ρ1 and the second coefficient of linear thermal expansion is expressed by ρ2, a value defined by “ρ2−ρ1” may be greater than or equal to −2.0×10⁻⁶/° C. and less than or equal to −1.0×10⁻⁶/° C. In this case, thermal stress generated in a main electrode is further easily suppressed.

[5] In [1] to [4], a thickness of the buffer plate may be less than a thickness of the semiconductor chip. In this case, although details will be described later, chipping, cracking, and the like of a semiconductor chip are easily suppressed, an incidence of failure is easily kept low, and heat is easily diffused through a buffer plate.

[6] In [1] to [5], the buffer plate includes a laminated material or an iron-nickel alloy material, and the laminated material may include a first copper layer in contact with the bonding material, an iron-nickel alloy layer provided on the first copper layer, and a second copper layer provided on the iron-nickel alloy layer. In this case, a wire can be electrically connected to a main electrode via a buffer plate by bonding the wire to the buffer plate. With this arrangement, even when ultrasonic bonding is adopted for bonding the wire, damage to a semiconductor chip can be suppressed. When the buffer plate is made of an iron-nickel alloy material, the buffer plate does not include a first copper layer and a second copper layer, and the iron-nickel alloy material is connected to the wire.

[7] In [6], the first copper layer and the second copper layer have a same thickness, and a thickness of the iron-nickel alloy layer may be 72/14 times or more the thickness of each of the first copper layer and the second copper layer. In this case, a second coefficient of linear thermal expansion is easily kept low.

[8] In [1] to [7], the semiconductor device may further include a wire bonded to the buffer plate. In this case, conduction between a main electrode and an external part can be secured via a wire.

[9] In [8], the wire may be a copper wire. In this case, a wire is easily bonded to a buffer plate, and the wire easily has the low electrical resistance.

In [8] or [9], a crystal grain extending from the wire toward the buffer plate may be provided at an interface between the wire and the buffer plate. In this case, a strong bond is easily obtained between a wire and a buffer plate.

In [1] to [5], the buffer plate includes a first copper layer in contact with the bonding material, an iron-nickel alloy layer provided on the first copper layer, and a second copper layer provided on the iron-nickel alloy layer, and the semiconductor device further includes a wire bonded to the buffer plate. The wire is a copper wire, and a crystal grain extending from the wire toward the buffer plate may be provided at an interface between the wire and the buffer plate. In this case, a strong bond is easily obtained between a wire and a second copper layer.

In [11], the crystal grain may extend to the iron-nickel alloy layer. In this case, a stronger bond is easily obtained.

In or [12], the first copper layer and the second copper layer have a same thickness, and a thickness of the iron-nickel alloy layer may be 72/14 times or more the thickness of each of the first copper layer and the second copper layer. In this case, a second coefficient of linear thermal expansion is easily kept low.

In [8] to [13], when viewed from a direction perpendicular to a main surface of the semiconductor substrate, the bonding material includes a first region overlapping a portion of the buffer plate to which the wire is bonded, and a second region around the first region. A coefficient of linear thermal expansion of the first region may be less than a coefficient of linear thermal expansion of the second region. In this case, stress acting on a main electrode is easily reduced.

In [14], the first region is formed of silicon carbide, silicon, silicon oxide, silicon nitride, an iron-nickel alloy, molybdenum, or tungsten, and the second region may be formed of copper, silver, nickel, or a sintered body of an intermetallic compound containing copper and tin. In this case, it is easy to reduce stress acting on a main electrode while ensuring excellent bonding strength.

In [8] to [13], when viewed from a direction perpendicular to a main surface of the semiconductor substrate, a gap may be provided in a portion of the bonding material that overlaps with a portion of the buffer plate to which the wire is bonded. In this case, stress acting on a main electrode is easily reduced.

In [1] to [16], the main electrode includes a plating layer, and the plating layer may be provided between the aluminum or aluminum alloy layer and the buffer plate. In this case, a main electrode is likely to have excellent corrosion resistance.

In [1] to [17], in a power cycling test in which a maximum junction temperature in each cycle for the semiconductor chip is set to 200° C. or higher, an increase in the maximum junction temperature may be 5.0° C. or lower, in a case where the number of repetitions is 200,000 to 300,000. In this case, the life is easily extended.

In [1] to [18], under a condition in which a temperature of the buffer plate increases from 25° C. to 250° C., subsequently an increased temperature decreases from 250° C. to 25° C., and a coefficient of linear thermal expansion of the buffer plate is continuously measured during increasing and decreasing of the temperature, when a coefficient of linear thermal expansion of the buffer plate during the increasing of the temperature is expressed by ρ5 and a coefficient of linear thermal expansion of the buffer plate during the decreasing of the temperature is expressed by ρ4, a maximum value for a value that is defined by “ρ5−ρ4” and is derived by a same temperature in the range of from 25° C. to 250° C. may be 1.5×10⁻⁶/° C. or less. In this case, the life is easily extended.

In [1] to [19], the semiconductor chip may be a silicon carbide chip. A silicon carbide chip has excellent high-temperature resistance, and the silicon carbide chip is unlikely to fail even when used at a high temperature. Also, the silicon carbide chip has increased mechanical characteristics. Further, internal fracture of a main electrode containing aluminum is suppressed, and thus a semiconductor device as a whole can easily have a long life even at a high temperature.

### Details of Embodiments of the Present Disclosure

Hereinafter, embodiments of the present disclosure will be described in detail, but these embodiments are not limiting. In the specification and the drawings, components having substantially the same functional configuration are denoted by the same reference numerals, and redundant description may be omitted. In the present specification and drawings, an X1-X2 direction, a Y1-Y2 direction, and a Z1-Z2 direction are directions orthogonal to one another. A plane including the X1-X2 direction and the Y1-Y2 direction is defined as an XY plane, a plane including the Y1-Y2 direction and the Z1-Z2 direction is defined as a YZ plane, and a plane including a Z1-Z2 direction and the X1-X2 direction is defined as a ZX plane. For the purpose of convenience, a Z1 direction is an upward direction, and a Z2 direction is a downward direction. In the present disclosure, a plan view means that an object is viewed from a Z1 side.

### First Embodiment

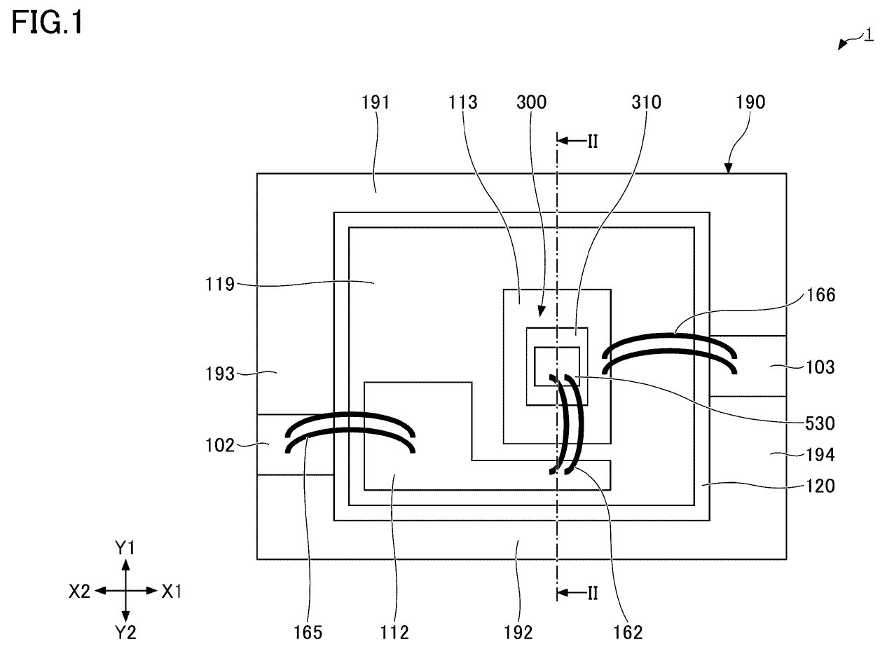

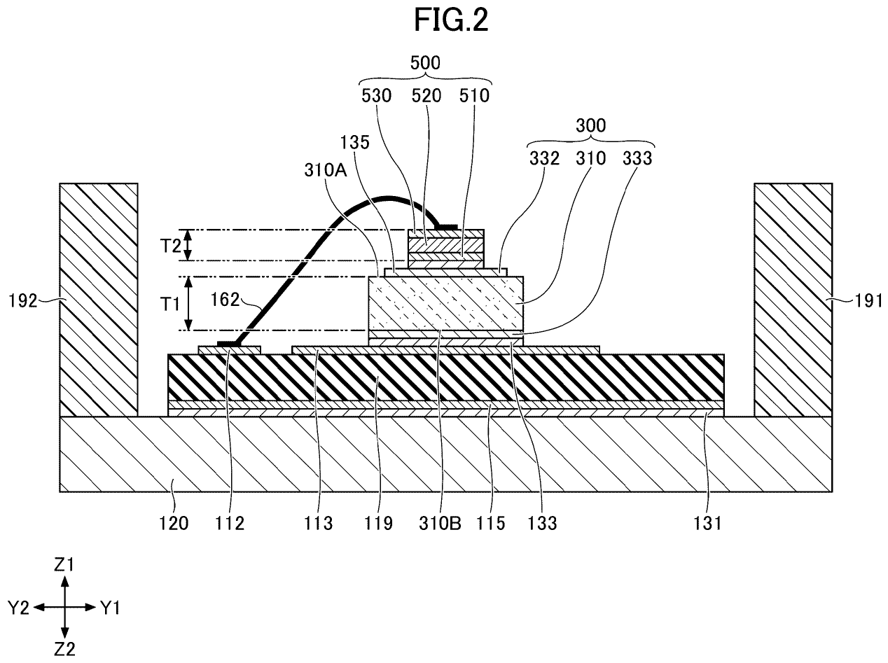

A first embodiment relates to a semiconductor device. FIG. 1 is a top view showing the semiconductor device according to the first embodiment. FIG. 2 is a cross-sectional view showing the semiconductor device according to the first embodiment. FIG. 2 corresponds to a cross-sectional view taken along line II-II in FIG. 1.

As shown in FIGS. 1 and 2, a semiconductor device 1 according to the first embodiment mainly includes a heat sink 120, a substrate 110, a terminal 102, a terminal 103, a case 190, a diode 300, and a buffer plate 500.

The heat sink 120 is, for example, a plate-like body having a rectangular shape, in a plan view, of which thickness is uniform. The material of the heat sink 120 is a metal that is a material having high thermal conductivity, such as copper (Cu), a copper alloy, aluminum (Al), or an aluminum-silicon-carbon alloy (Al—Si—C alloy). The heat sink 120 is fixed to a cooler or the like by using a thermal interface material (TIM) or the like.

The case 190 is formed to have a frame shape in a plan view, for example, and the outer shape of the case 190 is the same as the outer shape of the heat sink 120. The material of the case 190 is an insulator such as a resin. The case 190 includes a pair of opposed sidewalls 191 and 192 and a pair of end walls 193 and 194 each of which connects respective ends of the sidewalls 191 and 192. The sidewalls 191 and 192 are arranged in parallel to the ZX plane, and the end walls 193 and 194 are arranged in parallel to the YZ plane. The sidewall 191 is disposed on the Y1 side of the sidewall 192, and the end wall 193 is disposed on the X2 side of the end wall 194.

The terminal 102 is disposed on the upper surface (Z1 side-surface) of the end wall 193, and the terminal 103 is disposed on the upper surface (Z1 side-surface) of the end wall 194. The terminals 102 and 103 are each formed of a metal plate.

Inside the case 190, the substrate 110 is disposed on the Z1 side of the heat sink 120. The substrate 110 includes an insulating substrate 119, a second conductive pattern 112, a third conductive pattern 113, and a conductive layer 115. The first conductive pattern 111, the second conductive pattern 112, the third conductive pattern 113, the fourth conductive pattern 114, and the conductive layer 115 are made of Cu.

The second conductive pattern 112 and the third conductive pattern 113 are provided on a Z1-side surface of the insulating substrate 119. The conductive layer 115 is provided on a Z2-side surface of the insulating substrate 119. The conductive layer 115 is bonded to the heat sink 120 via a bonding material 131. The bonding material 131 may be a solder material or a sintered bonding material. When the bonding material 131 is a sintered bonding material, operations can be performed at a higher temperature near or above a melting point of solder.

As shown in FIG. 2, the diode 300 mainly includes a silicon carbide substrate 310, an anode electrode 332, and a cathode electrode 333.

The silicon carbide substrate 310 has a main surface 310A and a main surface 310B opposite the main surface 310A. The main surface 310A is on the Z1 side of the main surface 310B. The silicon carbide substrate 310 has, for example, a rectangular parallelepiped shape. The main surfaces 310A and 310B are surfaces parallel to the XY plane. The anode electrode 332 is provided on the main surface 310A, and the cathode electrode 333 is provided on the main surface 310B. The diode 300 is provided over the third conductive pattern 113. The anode electrode 332 includes, for example, an aluminum layer. The anode electrode 332 may include an aluminum alloy layer such as an aluminum-silicon alloy (Al—Si alloy) or an Al—Si—Cu alloy, instead of the aluminum layer. The cathode electrode 333 includes an ohmic layer and a bonding layer provided on the ohmic layer. The ohmic layer includes, for example, nickel or a nickel alloy. The nickel or the nickel alloy has a good contact resistance with silicon carbide. The bonding layer includes a nickel layer. The bonding layer may further include a gold layer or a silver layer that is provided on the nickel layer. When the cathode electrode 333 has the bonding layer, good bonding properties are obtained between the cathode electrode 333 and the third conductive pattern 113. The cathode electrode 333 is bonded to the third conductive pattern 113 by using a bonding material 133 such as a silver sintered body or a copper sintered body. The diode 300 is an example of a semiconductor chip. The silicon carbide substrate 310 is an example of a semiconductor substrate. The anode electrode 332 is an example of a main electrode.

The buffer plate 500 is, for example, a laminated material including a first copper layer 510, an iron-nickel alloy layer 520, and a second copper layer 530. The iron-nickel layer 520 is provided on the Z1 side of the first copper layer 510, and the second copper layer 530 is provided on the Z1 side of the iron-nickel layer 520. That is, the iron-nickel alloy layer 520 is provided on the first copper layer 510, and the second copper layer 530 is provided on the iron-nickel alloy layer 520. The iron-nickel alloy layer 520 is, for example, a layer of an iron-nickel alloy containing 36 wt % nickel. The iron-nickel alloy layer 520 may contain about 0.7 wt % manganese. The iron-nickel alloy layer 520 may contain about 17 wt % cobalt. The material of the iron-nickel alloy layer 520 may be invar (registered trademark). A thickness T2 of the buffer plate 500 is, for example, greater than or equal to 0.05 mm and less than or equal to 0.25 mm. For example, the thickness T2 of the buffer plate 500 is less than a thickness T1 of the diode 300. The buffer plate 500 is provided over the anode electrode 332. The first copper layer 510 is bonded to the anode electrode 332 by using a bonding material 135 such as a silver sintered body or a copper sintered body.

The silicon carbide substrate 310 has a first coefficient of linear thermal expansion ρ1, the buffer plate 500 has a second coefficient of linear thermal expansion ρ2, and the anode electrode 332 has a third coefficient of linear thermal expansion ρ3. Each coefficient of linear thermal expansion in the present disclosure is a coefficient of linear thermal expansion that is defined in a direction parallel to the main surface 310A and at 25° C., unless otherwise specified. The coefficient of linear thermal expansion in the present disclosure is a coefficient of linear thermal expansion that is obtained when a bonded state is released and thus the silicon carbide substrate 310, the buffer plate 500, and the anode electrode 332 are used as separate bodies, unless otherwise specified. The first coefficient of linear thermal expansion ρ1 and the second coefficient of linear thermal expansion ρ2 are each less than the third coefficient of linear thermal expansion ρ3, and the second coefficient of linear thermal expansion ρ2 is less than the first coefficient of linear thermal expansion ρ1. For example, the first coefficient of linear thermal expansion ρ1 is 4.0×10⁻⁶/° C., while the second coefficient of linear thermal expansion ρ2 is greater than or equal to 1.2×10⁻⁶/° C. and less than or equal to 3.9×10⁻⁶/° C. In this case, a value defined by “ρ2−ρ1” is greater than or equal to −2.8×10⁻⁶/° C. and less than or equal to −0.1×10⁻⁶/° C. A coefficient of linear thermal expansion of the iron-nickel alloy is about 1.2×10⁻⁶/° C., a coefficient of linear thermal expansion of copper is about 16.5×10⁻⁶/° C., and a coefficient of linear thermal expansion of aluminum is about 23.1×10⁻⁶/° C.

The semiconductor device 1 further includes wires 162, 165, and 166. The number of wires, for each of the wires 162, 165, and 166, is not limited, and may be one, or may be two or more.

The wire 162 connects the second copper layer 530 of the buffer plate 500 and the second conductive pattern 112 to each other. The wire 165 connects the second conductive pattern 112 and the terminal 102 to each other. The wire 166 connects the third conductive pattern 113 and the terminal 103 to each other. The wires 162, 165, and 166 are, for example, copper wires. The diameter of each of the wires 162, 165, and 166 is, for example, greater than or equal to 100 μm and less than or equal to 400 μm. The wires 162, 165, and 166 are bonded by, for example, ultrasonic bonding.

Here, when focusing on thermal deformation of the silicon carbide substrate 310 and the anode electrode 332, because the first coefficient of linear thermal expansion ρ1 is less than the third coefficient of linear thermal expansion ρ3, the anode electrode 332 may thermally deform as compared to the silicon carbide substrate 310. When the silicon carbide substrate 310 and the anode electrode 332 are firmly bonded to each other, greater thermal stress would occur on the anode electrode 332 in accordance with an increasing difference between the first coefficient of linear thermal expansion ρ1 and the third coefficient of linear thermal expansion ρ3, and as a result, internal fracture is likely to occur in the anode electrode 332.

On the other hand, the buffer plate 500 is bonded to the anode electrode 332 via the bonding material 135, and the thermal deformation of the anode electrode 332 is restrained by the buffer plate 500. In the present embodiment, the second coefficient of linear thermal expansion ρ2 of the buffer plate 500 is less than the first coefficient of linear thermal expansion ρ1. With this arrangement, the thermal deformation of the anode electrode 332 can be greatly suppressed by the bonding material 135. Therefore, in the present embodiment, thermal stress generated in the anode electrode 332 due to thermal deformation is suppressed, and internal fracture of the anode electrode 332 containing aluminum can be suppressed.

The thickness T2 of the buffer plate 500 is not particularly limited, and is, for example, greater than or equal to 0.05 mm and less than or equal to 0.25 mm. The thickness T2 may be greater than or equal to 0.07 mm and less than or equal to 0.23 mm, or may be greater than or equal to 0.10 mm and less than or equal to 0.20 mm. If the thickness T2 is excessively great, the electric resistance between the anode electrode 332 and the wire 162 may be excessively increased, or heat dissipation from the anode electrode 332 may be easily hindered. If the thickness T2 is excessively small, it may be difficult to suppress thermal deformation of the anode 332.

The thickness T2 of the buffer plate 500 is preferably less than the thickness T1 of the diode 300. This is because the inventors of this application have confirmed the following three items through a systematic test and its analysis.

In a first item, it has been confirmed that chipping, cracking, or the like in the diode 300 is likely to occur in a mounting and assembling stage in which the buffer plate 500 thicker than the diode 300 is mounted. This is because when the first coefficient of linear thermal expansion ρ1 of the silicon carbide substrate 310 and the second coefficient of linear thermal expansion ρ2 of the buffer plate 500 are different from each other, the buffer plate 500 tends to thermally deform more greatly in accordance with a greater thickness of the buffer plate 500, due to thermal stress generated between the silicon carbide substrate 310 and the buffer plate 500. When the thickness T2 of the buffer plate 500 is greater than the thickness T1 of the diode 300, thermal deformation is increased significantly, and chipping, cracking, or the like is considered to occur in the diode 300 (see No. 10 in Table 1 described later). This is presumably because yield strength of the iron-nickel alloy is 140 GPa, whereas the yield strength of silicon carbide is 40 GPa, and as a result, silicon carbide cannot withstand such toughened mechanical properties of the iron-nickel alloy.

In a second item, it has been found that an incidence of failure is significantly high in the semiconductor device in which the buffer plate 500 thicker than the diode 300 is mounted. This is considered to be because the resistivity of an iron-nickel alloy material itself is 10 times or more the resistivity of copper and aluminum that are conductor materials, which are typically used for an electronic part, and therefore, heat generation during operation is further increased. The resistivity of copper is 1.68×10⁻⁸ Ωm, the resistivity of aluminum is 2.65×10⁻⁸ Ωm, and the resistivity of iron-nickel alloy is 70×10⁻⁸ Ωm.

In a third item, as a result of careful analysis by the inventors of this application, it has been found that when the thickness T2 of the buffer plate 500 is greater than the thickness T1 of the diode 300, heat does not substantially diffuse into the buffer plate 500, because the thermal conductivity of the iron-nickel alloy is 0.1 times or less the thermal conductivity of silicon carbide. The thermal conductivity of the silicon carbide is 120 W/mK, and the thermal conductivity of the iron-nickel alloy is 13 W/mK. In addition, due to the high resistivity as described in the above second item, generated heat is increased, and also, the heat cannot be removed. As a result, it is considered to be a cause of accelerated deterioration (see Nos. 7, 8, 9, and 10 in Table 1 below).

In a series of processes, the thickness T2 of the diode 300 is 350 μm, and the highest temperature among test temperatures is 200° C.

In the present embodiment, when the wire 162 is bonded to the buffer plate 500, the wire 162 can be electrically connected to the anode electrode 332 via the buffer plate 500. With this arrangement, even when ultrasonic bonding is adopted for bonding the wire 162, damage to the diode 300 can be suppressed. When the wire 162 is a copper wire, the wire 162 is easily bonded to the second copper layer 530 of the buffer plate 500, and the wire 162 easily provides low electrical resistance.

A value defined by “ρ2−ρ1” is not particularly limited, and is, for example, greater than or equal to −2.8×10⁻⁶/° C. and less than or equal to −0.1×10⁻⁶/° C. The value defined by “ρ2−ρ1” may be greater than or equal to −2.0×10⁻⁶/° C. and less than or equal to −1.0×10⁻⁶/° C., or may be greater than or equal to −1.8×10⁻⁶/° C. and less than or equal to −1.2×10⁻⁶/° C. When the value defined by “ρ2−ρ1” is negative, internal fracture of the anode electrode 332 can be suppressed due to difference in thermal deformation. On the other hand, as the value defined by “ρ2−ρ1” becomes closer to 0, it may be difficult to suppress the thermal deformation of the anode electrode 332. If the value defined by “ρ2−ρ1” is excessively small, internal fracture may occur in the anode electrode 332 due to the difference in thermal deformation between the buffer plate 500 and the anode electrode 332.

In view of the above situation, it is particularly preferable that the thickness T2 of the buffer plate 500 is greater than or equal to 0.10 mm and less than or equal to 0.20 mm, and that the value defined by “ρ2−ρ1” is greater than or equal to −2.0×10⁻⁶/° C. and less than or equal to −1.0×10⁻⁶/° C.

For the configuration of the buffer plate 500, the thicknesses of the first copper layer 510 and the second copper layer 530 are equal to each other, and the thickness of the iron-nickel alloy layer 520 is preferably 72/14 times or more, more preferably 8 times or more, and further preferably 18 times or more, the thickness of each of the first copper layer 510 and the second copper layer 530. In this case, the second coefficient of linear thermal expansion ρ2 is suppressed to be small in accordance with an increasing percentage of the iron-nickel alloy layer 520.

When the thickness of the iron-nickel alloy layer 520 is 72/14 times the thickness of each of the first copper layer 510 and the second copper layer 530, the ratio of “the first copper layer 510:the iron-nickel alloy layer 520:the second copper layer 530”=“14%:72%:14%” is expressed in percentage of the thicknesses. In this case, the second coefficient of linear thermal expansion ρ2 of the buffer plate 500 is, for example, 3.8×10⁻⁶/° C., and the value defined by “ρ2−ρ1” is, for example, −0.2×10⁻⁶/° C.

When the thickness of the iron-nickel alloy layer 520 is eight times the thickness of each of the first copper layer 510 and the second copper layer 530, the ratio of “the first copper layer 510:the iron-nickel alloy layer 520:the second copper layer 530”=“10%:80%:10%” is expressed in percentage of the thicknesses. In this case, the second coefficient of linear thermal expansion ρ2 of the buffer plate 500 is, for example, 3.0×10⁻⁶/° C., and the value defined by “ρ2−ρ1” is, for example, −1.0×10⁻⁶/° C.

When the thickness of the iron-nickel alloy layer 520 is 18 times the thickness of each of the first copper layer 510 and the second copper layer 530, the ratio of “the first copper layer 510:the iron-nickel alloy layer 520:the second copper layer 530”=“5%:90%:5%” is expressed in percentage of the thicknesses. In this case, the second coefficient of linear thermal expansion ρ2 of the buffer plate 500 is, for example, 2.1×10⁻⁶/° C., and the value defined by “ρ2−ρ1” is, for example, −2.1×10⁻⁶/° C., and the value defined by “ρ2−ρ1” is, for example, −1.9×10⁻⁶/° C.

The buffer plate 500 may not include the first copper layer 510 and the second copper layer 530. That is, the buffer plate 500 may be formed of the iron-nickel alloy layer 520 such as invar. In this case, the second coefficient of linear thermal expansion ρ2 of the buffer plate 500 is, for example, 1.2×10⁻⁶/° C., and the value defined by “ρ2−ρ1” is, for example, −2.8×10⁻⁶/° C.

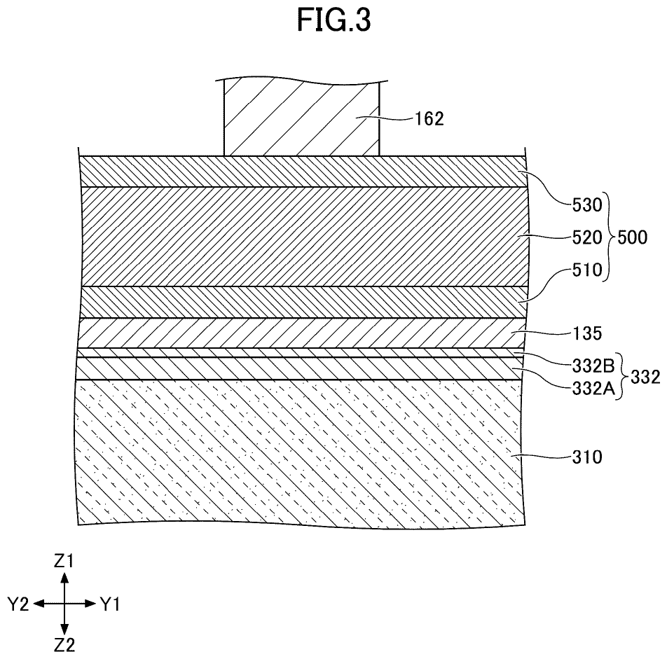

The anode electrode 332 preferably includes a plating layer formed on the aluminum layer, in addition to including the aluminum layer. FIG. 3 is a cross-sectional view showing an example of the source electrode.

For example, as shown in FIG. 3, the anode electrode 332 may include an aluminum layer 332A and a plating layer 332B. The aluminum layer 332A is located on a silicon carbide substrate 310-side (Z2 side) of the plating layer 332B, and the plating layer 332B covers a Z1-side surface of the aluminum layer 332A. The plating layer 332B is provided between the aluminum layer 332A and the buffer plate 500. The plating layer 332B is, for example, a nickel plating layer. The plating layer 332B may include, for example, a nickel plating layer, a palladium plating layer provided on the nickel plating layer, and a gold plating layer provided on a palladium layer. When the anode electrode 332 includes the plating layer 332B, the anode electrode 332 has excellent corrosion resistance. Further, when the anode electrode 332 includes the plating layer 332B, it is possible to provide an excellent electrical connection and mechanical connection, between the anode 332 and the bonding material 135, such as low electric resistance, high bonding strength, and high reliability.

A plurality of diodes 300 may be provided on the third conductive pattern 113. In this case, the plurality of diodes 300 are electrically connected in parallel to each other.

### Second Embodiment

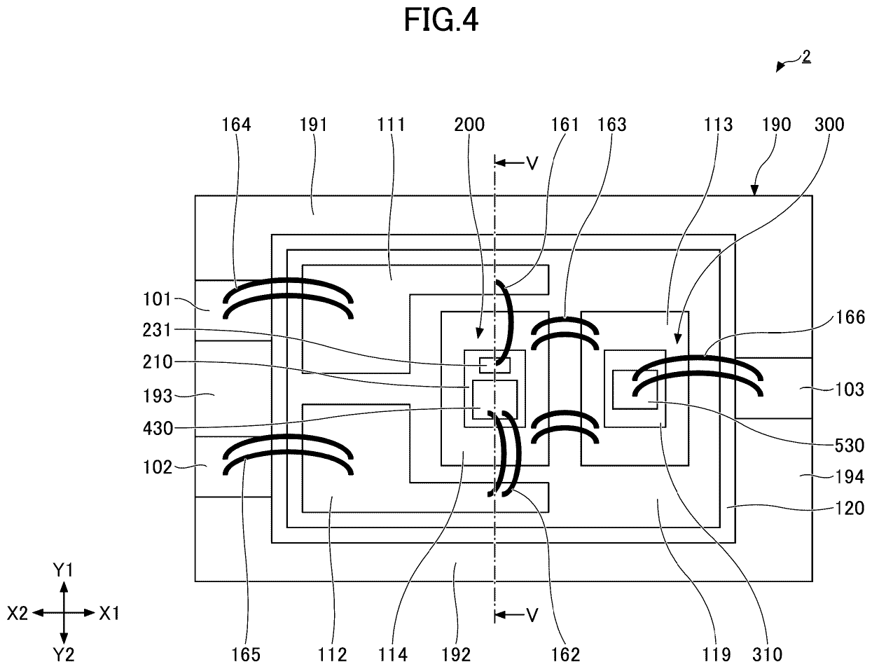

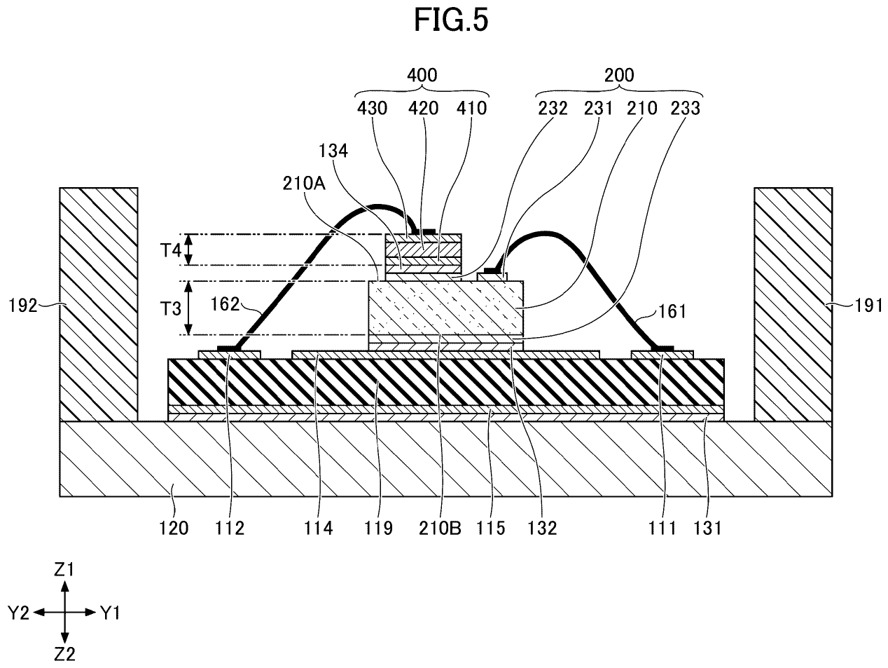

Next, a second embodiment will be described. The second embodiment differs from the first embodiment mainly in that the second embodiment provides a transistor. FIG. 4 is a top view showing the semiconductor device according to the second embodiment. FIG. 5 is a cross-sectional view showing the semiconductor device according to the second embodiment. FIG. 5 corresponds to a cross-sectional view taken along the line V-V in FIG. 4.

As shown in FIGS. 4 and 5, a semiconductor device 2 according to the second embodiment mainly includes the heat sink 120, the substrate 110, the terminal 101, the terminal 102, a terminal 103, the case 190, a transistor 200, the diode 300, a buffer plate 400, and the buffer plate 500.

The terminals 101 and 102 are disposed on the upper surface (Z1-side surface) of the end wall 193, and the terminal 103 is disposed on the upper surface (Z1-side surface) of the end wall 194. For example, the terminal 102 is disposed on the Y2 side of the terminal 101. The terminals 101, 102, and 103 are each formed of a metal plate.

The substrate 110 includes an insulating substrate 119, a first conductive pattern 111, a second conductive pattern 112, a third conductive pattern 113, a fourth conductive pattern 114, and a conductive layer 115. The first conductive pattern 111, the second conductive pattern 112, the third conductive pattern 113, the fourth conductive pattern 114, and the conductive layer 115 are made of Cu.

The first conductive pattern 111, the second conductive pattern 112, the third conductive pattern 113, and the fourth conductive pattern 114 are provided on a 21-side surface of the insulating substrate 119. The conductive layer 115 is provided on a Z2-side surface of the insulating substrate 119.

As shown in FIG. 5, the transistor 200 mainly includes a silicon carbide substrate 210, a gate electrode 231, a source electrode 232, and a drain electrode 233.

The silicon carbide substrate 210 has a main surface 210A and a main surface 210B opposite the main surface 210A. The main surface 210A is on the Z1 side of the main surface 210B. The silicon carbide substrate 210 has, for example, a rectangular parallelepiped shape. The main surfaces 210A and 210B are surfaces parallel to the XY plane. The gate electrode 231 and the source electrode 232 are provided on the main surface 210A, and the drain electrode 233 is provided on the main surface 210B. The transistor 200 is provided on the fourth conductive pattern 114. The gate electrode 231 and the source electrode 232 include, for example, an aluminum layer. The gate electrode 231 and the source electrode 232 may include an aluminum alloy layer such as an Al—Si alloy or an Al—Si—Cu alloy, instead of the aluminum layer. The drain electrode 233 includes an ohmic layer and a bonding layer provided on the ohmic layer. The ohmic layer includes, for example, nickel or a nickel alloy. The nickel or a nickel alloy has good contact resistance with silicon carbide. The bonding layer includes a nickel layer. The bonding layer may further include a gold layer or a silver layer provided on the nickel layer. Since the drain electrode 233 has the bonding layer, good bonding properties are obtained between the drain electrode 233 and the fourth conductive pattern 114. The thickness T1 of the transistor 200 is, for example, about 0.35 mm. In a plan view, the length of each side of the transistor 200 is, for example, about 3 mm. The drain electrode 233 is bonded to the fourth conductive pattern 114 using a bonding material 132 such as a silver sintered body or a copper sintered body. The transistor 200 is an example of a semiconductor chip. The silicon carbide substrate 210 is an example of a semiconductor substrate. The source electrode 232 is an example of a main electrode.

The buffer plate 400 is, for example, a laminated material including a first copper layer 410, an iron-nickel alloy layer 420, and a second copper layer 430. The iron-nickel layer 420 is provided on the Z1 side of the first copper layer 410, and the second copper layer 430 is provided on the Z1 side of the iron-nickel layer 420. That is, the iron-nickel alloy layer 420 is provided on the first copper layer 410, and the second copper layer 430 is provided on the iron-nickel alloy layer 420. The iron-nickel alloy layer 420 is, for example, a layer of an iron-nickel alloy containing 36 wt % nickel. The iron-nickel alloy layer 420 may contain about 0.7 wt % manganese. The iron-nickel alloy layer 420 may contain about 17 wt % cobalt. The material of the iron-nickel alloy layer 420 may be invar. A thickness T4 of the buffer plate 400 is, for example, greater than or equal to 0.05 mm and less than or equal to 0.25 mm. For example, the thickness T4 of the buffer plate 400 is less than a thickness T3 of the transistor 200. The buffer plate 400 is provided on the source electrode 232. The first copper layer 410 is bonded to the source electrode 232 by using a bonding material 134 such as a silver sintered body or a copper sintered body.

The silicon carbide substrate 210 has a first coefficient of linear thermal expansion ρ1′, the buffer plate 400 has a second coefficient of linear thermal expansion ρ2′, and the source electrode 232 has a third coefficient of linear thermal expansion ρ3′. Each coefficient of linear thermal expansion in the present disclosure is a coefficient of linear thermal expansion that is defined in a direction parallel to the main surface 210A and at 25° C., unless otherwise specified. The coefficient of linear thermal expansion in the present disclosure is a coefficient of linear thermal expansion when a bonded state is released and thus the silicon carbide substrate 210, the buffer plate 400, and the source electrode 232 are used as separate bodies, unless otherwise specified. The first coefficient of linear thermal expansion ρ1′ and the second coefficient of linear thermal expansion ρ2′ are less than the third coefficient of linear thermal expansion ρ3′, and the second coefficient of linear thermal expansion ρ2′ is less than the first coefficient of linear thermal expansion ρ1′. For example, the first coefficient of linear thermal expansion ρ1′ is 4.0×10⁻⁶/° C., while the second coefficient of linear thermal expansion ρ2′ is greater than or equal to 1.2×10⁻⁶/° C. and less than or equal to 3.9×10⁻⁶/° C. In this case, a value defined by “ρ2′−ρ1′” is greater than or equal to −2.8×10⁻⁶/° C. and less than or equal to −0.1×10⁻⁶/° C.

The semiconductor device 2 further includes wires 161, 162, 163, 164, 165, and 166. The number of wires, for each of the wires 161 to 166, is not limited, and may be one or two or more.

The wire 161 connects the gate electrode 231 of the transistor 200 and the first conductive pattern 111 to each other. The wire 162 connects the second copper layer 430 of the buffer plate 400 and the second conductive pattern 112 to each other. The wire 163 connects the third conductive pattern 113 and the fourth conductive pattern 114 to each other. The wire 164 connects the first conductive pattern 111 and the terminal 101 to each other. The wire 165 connects the second conductive pattern 112 and the terminal 102 to each other. The wire 166 connects the anode electrode 332 of the diode 300 and the terminal 103 to each other. The wires 161 to 166 are, for example, copper wires. The diameter of each of the wires 161 to 166 is, for example, greater than or equal to 100 μm and less than or equal to 400 μm. The wires 161 to 166 are bonded by, for example, ultrasonic bonding.

Other configurations, for example, the configurations of the diode 300 and the buffer plate 500 are the same as those described in the first embodiment.

Here, when focusing on thermal deformation of the silicon carbide substrate 210 and the source electrode 232, the source electrode 232 may thermally deform as compared to the silicon carbide substrate 210, because the first coefficient of linear thermal expansion ρ1′ is less than the third coefficient of linear thermal expansion ρ3′. If the silicon carbide substrate 210 and the source electrode 232 are firmly bonded to each other, thermal stress would occur on source electrode 232 greatly in accordance with an increasing difference between the first coefficient of linear thermal expansion ρ1′ and the third coefficient of linear thermal expansion ρ3′, and as a result, internal fracture is likely to occur in source electrode 232.

On the other hand, the buffer plate 400 is bonded to the source electrode 232 by using the bonding material 134, and the thermal deformation of the source electrode 232 is restrained by the buffer plate 400. In the present embodiment, the second coefficient of linear thermal expansion ρ2′ of the buffer plate 400 is less than the first coefficient of linear thermal expansion ρ1′. With this arrangement, thermal deformation of the source electrode 232 can be greatly suppressed by the bonding material 134. Thus, in the present embodiment, thermal stress generated in the source electrode 232 due to thermal deformation can be suppressed, and internal fracture of the source electrode 232 containing aluminum can be suppressed.

The thickness T4 of the buffer plate 400 is not particularly limited, and is, for example, greater than or equal to 0.05 mm and less than or equal to more than 0.25 mm. The thickness T4 may be greater than or equal to 0.07 mm and less than or equal to 0.23 mm, or may be greater than or equal to 0.10 mm and less than or equal to 0.20 mm. If the thickness T4 is excessively great, the electric resistance between the source electrodes 232 and the wires 162 may be excessively increased, or heat dissipation from the source electrodes 232 may be easily hindered. If the thickness T4 is excessively small, it may be difficult to suppress the thermal deformation of the source electrodes 232.

In particular, when the thickness T4 of the buffer plate 400 is less than the thickness T3 of the transistor 200, chipping, cracking, and the like in the transistor 200 is easily suppressed, an incidence of failure is easily kept low, and heat is easily diffused through the buffer plate 400, similarly to the relationship between the thickness T1 of the diode 300 and the thickness T2 of the buffer plate 500.

In the present embodiment, when the wire 162 is bonded to the buffer plate 400, the wire 162 can be electrically connected to the source electrode 232 via the buffer plate 400. With this arrangement, even when ultrasonic bonding is adopted for bonding the wire 162, damage to the transistor 200 can be suppressed. When the wire 162 is a copper wire, the wire 162 is easily bonded to the second copper layer 430 of the buffer plate 400, and the wire 162 easily has low electrical resistance.

The value defined by “ρ2′−ρ1′” is not particularly limited, and is, for example, greater than or equal to −2.8×10⁻⁶/° C. and less than or equal to −0.1×10⁻⁶/° C. The value defined by “ρ2′−ρ1′” may be greater than or equal to −2.0×10⁻⁶/° C. and less than or equal to −1.0×10⁻⁶/° C., or may be greater than or equal to −1.8×10⁻⁶/° C. and less than or equal to −1.2×10⁻⁶/° C. When “ρ2′−ρ1′” is negative, the internal fracture of the source electrode 232 can be suppressed by the difference in thermal deformation. On the other hand, as the value defined by “ρ2′−ρ1′” becomes closer to 0, it may be difficult to suppress the thermal deformation of the source electrode 232. If the value defined by “ρ2′−ρ1′” is excessively small, internal fracture may occur in the source electrode 232 due to the difference in thermal deformation between the buffer plate 400 and the source electrode 232.

From the above situation, it is particularly preferable that the thickness T4 of the buffer plates 400 is greater than or equal to 0.10 mm and less than or equal to 0.20 mm and the value defined by “ρ2′−ρ1′” is greater than or equal to −2.0×10⁻⁶/° C. and less than or equal to −1.0×10⁻⁶/° ° C.

For the configuration of the buffer plate 400, the thicknesses of the first copper layer 410 and the second copper layer 430 are equal to each other, and the thickness of the iron-nickel alloy layer 420 is preferably 72/14 times or more, more preferably 8 times or more, and further preferably 18 times or more the thickness of each of the first copper layer 410 and the second copper layer 430. In this case, as the proportion of the iron-nickel alloy layer 420 is increased, the second coefficient of linear thermal expansion ρ2′ is easily kept low.

When the thickness of the iron-nickel alloy layer 420 is 72/14 times the thickness of each of the first copper layer 410 and the second copper layer 430, the ratio “the first copper layer 410:the iron-nickel alloy layer 420:the second copper layer 430”=“14%:72%:14%” is expressed in percentage of the thicknesses. In this case, the second coefficient of linear thermal expansion ρ2′ of the buffer plate 400 is, for example, 3.8×10⁻⁶/° C., and the value defined by “ρ2′−ρ1′” is, for example, −0.2×10⁻⁶/° C.

When the thickness of the iron-nickel alloy layer 420 is eight times the thickness of each of the first copper layer 410 and the second copper layer 430, the ratio of “the first copper layer 410:the iron-nickel alloy layer 420:the second copper layer 430”=“10%:80%:10%” is expressed in percentage of the thicknesses. In this case, the second coefficient of linear thermal expansion ρ2′ of the buffer plate 400 is, for example, 3.0×10⁻⁶/° C., and the value defined by “ρ2′−ρ1′” is, for example, −1.0×10⁻⁶/° C.

When the thickness of the iron-nickel alloy layer 420 is 18 times the thickness of each of the first copper layer 410 and the second copper layer 430, the ratio of “the first copper layer 410:the iron-nickel alloy layer 420:the second copper layer 430”=“5%:90%:5%” is expressed in percentage of the thicknesses. In this case, the second coefficient of linear thermal expansion ρ2′ of the buffer plate 400 is, for example, 2.1×10⁻⁶/° C., and the value defined by “ρ2′−ρ1′” is, for example, −1.9×10⁻⁶/° C.

The buffer plate 400 may not include the first copper layer 410 and the second copper layer 430. That is, the buffer plate 400 may be formed of the iron-nickel alloy layer 420 such as invar. In this case, the second coefficient of linear thermal expansion ρ2′ of the buffer plate 400 is, for example, 1.2×10⁻⁶/° C., and the value defined by “ρ2′−ρ1′” is, for example, −2.8×10⁻⁶/° C.

The source electrode 232 preferably includes a plating layer formed on the aluminum layer, in addition to including the aluminum layer, similarly to the anode electrode 332. The source electrode 232 includes the plating layer, and thus the source electrode 232 can have excellent corrosion resistance. Further, when the source electrode 232 includes the plating layer, it is possible to provide excellent electrical connection and mechanical connection, between the source electrode 232 and the bonding material 134, such as low electrical resistance, high bonding strength, and high reliability.

A plurality of transistors 200 may be provided on the fourth conductive pattern 114. In this case, the plurality of transistors 200 are electrically connected to each other in parallel.

### Third Embodiment

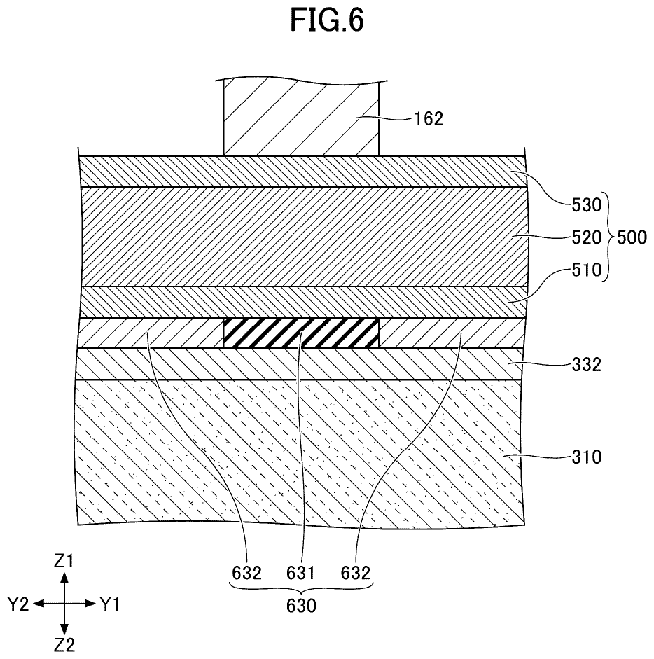

Next, a third embodiment will be described. The third embodiment differs from the first embodiment mainly in the configuration of the bonding material between the anode electrode 332 and the buffer plate 500. FIG. 6 is a cross-sectional view showing the bonding material between the anode electrode 332 and the buffer plate 500 according to the third embodiment.

As shown in FIG. 6, in the third embodiment, a bonding material 630 is provided instead of the bonding material 135. In a plan view, the bonding material 630 includes a first region 631 overlapping a portion of the buffer plate 500 to which the wire 162 is bonded, and includes a second region 632 around the first region 631. A coefficient of linear thermal expansion of the first region 631 is less than that of the second region 632. For example, the second region 632 includes a bonding material such as a silver sintered body or a copper sintered body, similarly to the bonding material 135. On the other hand, the first region 631 may be made of, for example, silicon carbide, silicon, silicon oxide, or silicon nitride. The silicon oxide may contain boron, and phosphorus doped silicon oxide may be used. The first region 631 may be made of a metal such as an iron-nickel alloy, molybdenum, or tungsten. The first region 631 may be made of a ceramic such as alumina and zircon.

Other configurations are the same as those described in the first embodiment.

The third embodiment also provides the same effects as described in the first embodiment.

In the third embodiment, the coefficient of linear thermal expansion of the first region 631 is less than the coefficient of linear thermal expansion of the second region 632, and thus, as described below, the stress acting on the anode electrode 332 can be reduced, and internal fracture of the anode electrode 332 can be further suppressed.

That is, because the wire 162 is connected to the second copper layer 530, thermal deformation of a portion of the second copper layer 530 to which the wire 162 is connected is greater than that of a surrounding portion. With this arrangement, in the cross section perpendicular to the X1-X2 direction (cross section parallel to the YZ plane), although the thickness of the first Cu layer 510 and the thickness of the second Cu layer 530 are equal, a portion of the buffer plate 500 having an increased second coefficient of linear thermal expansion ρ2 is locally formed, and the value defined by “ρ2−ρ1” may be increased. In the third embodiment, because the coefficient of linear thermal expansion of the first region 631 is less than the coefficient of linear thermal expansion of the second region 632, a local increase in the value defined by “ρ2−ρ1” can be suppressed, and internal fracture of the anode electrode 332 can be further suppressed.

When the value defined by “ρ2−ρ1” is locally excessively increased, a corresponding portion becomes fragile, and there is a high possibility of leading to the entire fracture from the corresponding portion as a starting point. In such a case, the life of the entire semiconductor device is determined by the life of the fragile portion in the power cycling test or the like.

The second region 632 is a bonding material such as a silver sintered body or a copper sintered body, and the first region 631 is made of silicon carbide, silicon oxide, or an iron-nickel alloy. With this arrangement, it is easy to reduce stress acting on the anode electrode 332 while ensuring excellent bonding strength.

### Fourth Embodiment

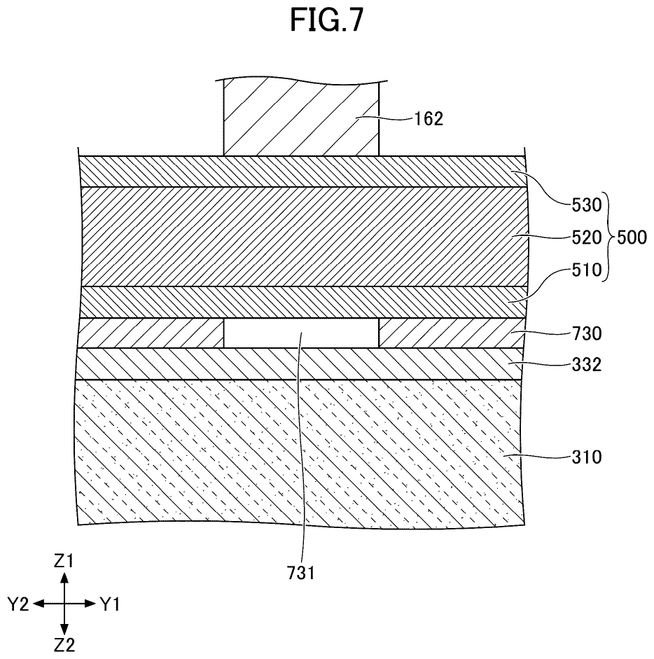

Next, a fourth embodiment will be described. The fourth embodiment differs from the first embodiment mainly in the configuration of the bonding material between the anode electrode 332 and the buffer plate 500. FIG. 7 is a cross-sectional view showing the bonding material between the anode electrode 332 and the buffer plate 500 according to the fourth embodiment.

As shown in FIG. 7, in the fourth embodiment, a bonding material 730 is provided instead of the bonding material 135. The bonding material 730 is a bonding material such as a silver sintered body or a copper sintered body, similarly to the bonding material 135. However, a gap 731 is provided in a portion of the bonding material 730 that overlaps with a portion of the buffer plate 500 to which the wire 162 is bonded in a plan view. Inside the gap 731, a gas such as air, hydrogen, nitrogen, or oxygen may be present, and the inside of the gap 731 may be in a vacuum state at a low pressure.

Other configurations are the same as those described in the first embodiment.

The fourth embodiment also provides the same effects as described the first embodiment.

In the fourth embodiment, the gap 731 is provided in the bonding material 730, and thus the stress acting on the anode electrode 332 is reduced. As a result, the internal fracture of the anode electrode 332 can be further suppressed, similarly to the third embodiment.

The width of each of the first region 631 in the third embodiment and the gap 731 in the Y1-Y2 direction in the fourth embodiment may correspond to the width of the wire 162. It has been confirmed from stress analysis using the finite element method that the generation of stress in the anode electrode 332 can be suppressed when the width of the first region 631 or the gap 731 is ¼ or more the width of the wire 162. On the other hand, if the width of the first region 631 or the gap 731 is excessively increased, a current path from the wire 162 to the diode 300 decreases. In this case, the width of the first region 631 or the gap 731 is preferably 5 times or less, more preferably 2 times or less, and still more preferably 1 time or less the width of the wire 162.

In the second embodiment, a bonding material similar to the bonding material 630 or 730 may be used instead of the bonding material 134. In this case, the stress acting on the source electrode 232 is easily reduced.

The wire 162 is bonded to the second copper layer 530, and crystal grains that straddle an interface between the wire 162 and the second copper layer 530 are preferably present at the interface between the wire 162 and the second copper layer 530. The crystal grains that straddle the interface between the wire 162 and the second copper layer 530 preferably extend to an interface with the iron-nickel alloy layer 520.

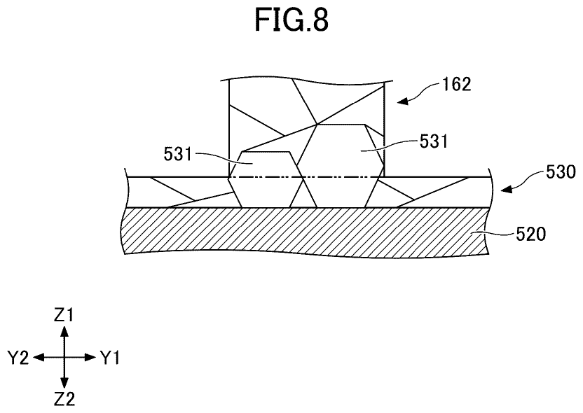

FIG. 8 is a diagram showing an example of the crystal grains constituting the wire 162 and the second copper layer 530. As shown in FIG. 7, a portion of the plurality of crystal grains 531 constituting the wire 162 and the second copper layer 530 may straddle the interface between the wire 162 and the second copper layer 530. When the crystal grains 531 straddling the interface between the wire 162 and the second copper layer 530 are present, it is easy to obtain a strong bond between the wire 162 and the second copper layer 530. Further, when the crystal grains 531 straddling the interface between the wire 162 and the second copper layer 530 extend to an interface with the iron-nickel alloy layer 420, a stronger bond is easily obtained.

### (Characteristic Test)

Next, desirable characteristics with respect to a temperature change that is obtained when the power cycling test is performed on the semiconductor device according to the embodiment of the present disclosure will be described. The following power cycling test is performed according to IEC60749.

In the power cycling test, after the temperature of a sample is increased from room temperature (25° C.) to 65° C., energization and interruption of the current of 125 A are repeated. An energization time period (tₒₙ) is set to 1 second, and an interruption time period (t_{off}) is set to 13 seconds. Further, a maximum junction temperature (Tjₘₐₓ), which is a maximum value of the junction temperature (Tj) in each cycle, is set to 200° C. or higher, and a difference (ΔTj) between the maximum junction temperature and a minimum junction temperature (65° C.) in each cycle is set to 135° C. or higher.

An energization-start voltage obtained when a small current of about 100 mA passes through the sample corresponds to the junction temperature (Tj) for the sample. In view of this situation, if the small current of 100 mA that is sufficiently less than the current applied immediately after energization is applied to the sample for each cycle of the energization and interruption, in a case where the energization-start voltage at this time is measured, an energization-start temperature in each cycle can be converted to the maximum junction temperature (Tjₘₐₓ). As the power cycling test is further performed, the resulting sample gradually deteriorates, and the maximum junction temperature (Tjₘₐₓ) gradually increases. In such a situation, a state where ΔTj increases by 20% after the start of the energization is defined as the end of life in this test. As described above, when the minimum junction temperature is 65° C. and the maximum junction temperature is 200° C., and ΔTj is 135° C., the temperature at which ΔTj increases by 20% is 162° C. In such a case, a state in which the maximum junction temperature (Tjₘₐₓ) reaches 227° C. is regarded as the end of life. The above test is performed according to the inspection standard IEC60749 specified by the international standardization organization, and lifetimes obtained between power module samples that have different structures and are obtained by different manufacturing methods can be compared under the same condition. The junction temperature in the present disclosure is obtained with the above approach.

In such a power cycling test, an increase in the maximum junction temperature (Tjₘₐₓ) obtained when the number of repetitions is 200,000 to 300,000 is preferably 5.0° C. or less, more preferably 4.5° C. or less, and still more preferably 4.0° C. or less. As the increase is reduced, internal fracture of the aluminum layer included in the anode electrode or the source electrode is easily suppressed.

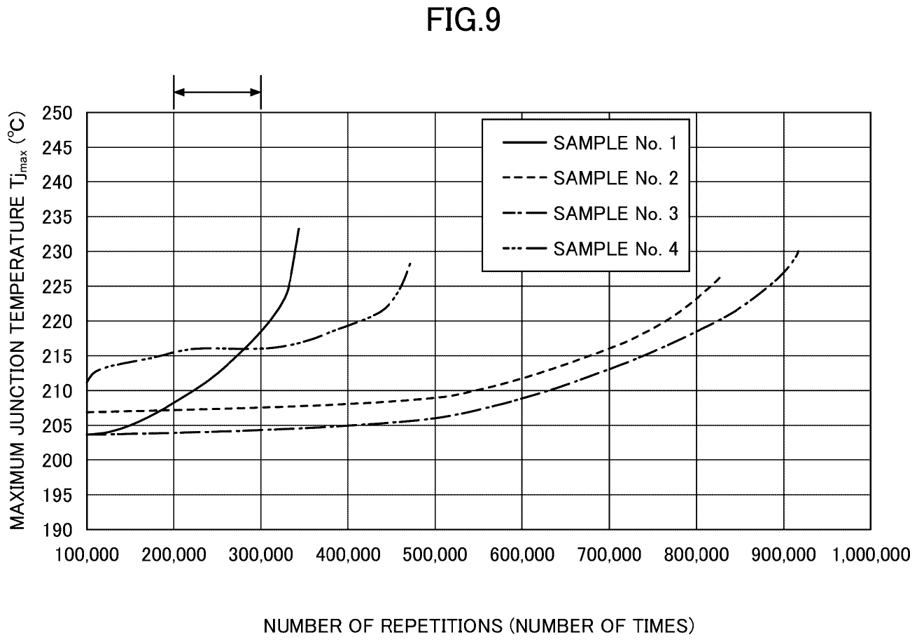

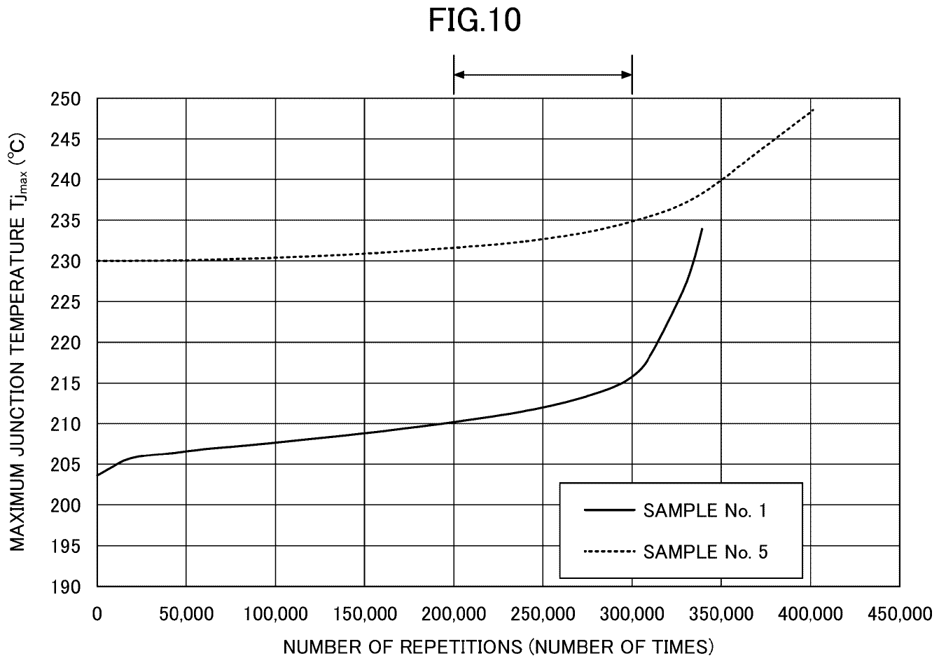

FIGS. 9 and 10 show examples of the results of the power cycling test. FIGS. 9 and 10 show the results of the power cycling test for 11 types of samples (samples No. 1 to No. 11) in total. In this power cycling test, a diode is used as each sample. In FIGS. 9 and 10, the horizontal axis represents the number of repetitions (the number of times) of energization and interruption, and the vertical axis represents the maximum junction temperature Tjₘₐₓ (° C.). A buffer plate has a different configuration with respect to each of samples No. 1 to No. 11, and other conditions are the same. As a semiconductor substrate, a silicon carbide substrate having a first coefficient of linear thermal expansion ρ1 of 4.0×10⁻⁶/° C. is used. Table 1 shows the overview of buffer plates of samples No. 1 to No. 11. Table 1 also shows the maximum junction temperature Tjₘₐₓ (initial temperature) at the start of the test, the maximum junction temperature Tjₘₐₓ (temperature when repeated 200,000 times) at a timing at which the number of repetitions is 200,000, and the increase in the maximum junction temperature Tjₘₐₓ obtained when the number of repetitions is 200,000 to 300,000. Table 1 further shows the number of repetitions at a timing (life end) at which ΔTj increases by 20%, the number of repetitions at a timing at which ΔTj increases by 5% before the end of life, and a ratio R of the number of repetitions at the timing at which ΔTj increases by 5%, to the number of repetitions obtained at the end of life.

TABLE 1

| | BUFFER PLATE | | | | | | |
|---|---|---|---|---|---|---|---|
| | | THICKNESS | | THICKNESS | | | |
| | | OF FIRST | THICKNESS | OF SECOND | | | |
| | | COPPER | OF Fe—Ni | COPPER | | | INITIAL |
| | THICKNESS | LAYER | ALLOY LAYER | LAYER | ρ2 | ρ2 − ρ1 | TEMPERATURE |
| SAMPLE | (mm) | (mm) | (mm) | (mm) | (×10⁻⁶/° C.) | (×10⁻⁶/° C.) | (° C.) |
| No. 1 | 0.10 | 0.020 | 0.060 | 0.020 | 5.2 | +1.2 | 203.9 |
| No. 2 | 0.20 | 0.020 | 0.160 | 0.020 | 3.0 | −1.0 | 207.1 |
| No. 3 | 0.20 | 0.010 | 0.180 | 0.010 | 2.1 | −1.9 | 202.9 |
| No. 4 | 0.10 | 0.005 | 0.090 | 0.005 | 2.1 | −1.9 | 212.6 |
| No. 5 | 0.10 | 0.010 | 0.080 | 0.010 | 3.0 | −1.0 | 229.3 |
| No. 6 | 0.10 | 0.000 | 0.100 | 0.000 | 1.2 | −2.8 | 205.1 |
| No. 7 | 0.30 | 0.030 | 0.240 | 0.030 | 3.0 | −1.0 | 208.3 |
| No. 8 | 0.30 | 0.015 | 0.270 | 0.015 | 2.1 | −1.9 | 202.8 |
| No. 9 | 0.60 | 0.060 | 0.480 | 0.060 | 3.0 | −1.0 | 201.2 |
| No. 10 | 0.60 | 0.015 | 0.270 | 0.015 | 2.1 | −1.9 | 210.3 |
| No. 11 | 0.05 | 0.0025 | 0.0450 | 0.0025 | 2.1 | −1.9 | 206.8 |

| | | INCREASE IN | LIFE | | |
|---|---|---|---|---|---|
| | | Tjₘₐₓ FROM | (NUMBER OF | NUMBER OF | |
| | TEMPERATURE | 200,000 | REPETITIONS | REPETITIONS | |
| | OBTAINED | TRIALS TO | IS INCREASED | IS INCREASED | |
| | IN 200,000 | 300,000 | BY 20% | BY 5% | RATIO |
| | TRIALS | TRIALS | (IN TEN | (IN TEN | R |
| SAMPLE | (° C.) | (° C.) | THOUSAND)) | THOUSAND) | (%) |
| No. 1 | 207.4 | 8.4 | 33.4 | 13.2 | 40 |
| No. 2 | 207.2 | 3.7 | 84.5 | 48.8 | 70 |
| No. 3 | 203.9 | 1.2 | 90.7 | 53.5 | 75 |
| No. 4 | 216.1 | 1.2 | 47.2 | 37.4 | 79 |
| No. 5 | 231.7 | 3.1 | 42.5 | 33.1 | 86 |
| No. 6 | 205.9 | 2.7 | 55.8 | 43.0 | 77 |
| No. 7 | 220.9 | 6.5 | 33.0 | 12.5 | 38 |
| No. 8 | 217.1 | 7.5 | 32.5 | 14.6 | 45 |
| No. 9 | 226.0 | 8.8 | 30.9 | 13.2 | 40 |
| No. 10 | — | — | LESS | — | — |
| | | | THAN 20.0 | | |
| No. 11 | 207.4 | 2.3 | 40.0 OR | — | — |
| | | | MORE | | |

As shown in FIGS. 9 and 10 and Table 1, in sample No. 1, the second coefficient of linear thermal expansion ρ2 of the buffer plate is greater than the first coefficient of linear thermal expansion ρ1 (4.0×10⁻⁶/° C.) of the semiconductor substrate, and a value defined by “ρ2−ρ1” is +1.2×10⁻⁶/° C. An increase in the maximum junction temperature (Tjₘₐₓ) is 8.4° C. An initial temperature of sample No. 1 at the start of the test is 203.9° C., and the end of life is obtained when repeated 334,000 times.

In sample No. 2, the second coefficient of linear thermal expansion ρ2 of the buffer plate is less than the first coefficient of linear thermal expansion ρ1 of the semiconductor substrate, and the value defined by “ρ2−ρ1” is −1.0×10⁻⁶/° C. The increase in the maximum junction temperature (Tjₘₐₓ) is 3.7° C. The initial temperature of sample No. 2 at the start of the test is 207.1° C., and the end of life is obtained when repeated 845,000 times.

In sample No. 3, the second coefficient of linear thermal expansion ρ2 of the buffer plate is less than the first coefficient of linear thermal expansion ρ1 of the semiconductor substrate, and the value defined by “ρ2−ρ1” is −1.9×10⁻⁶/° C. The increase in the maximum junction temperature (Tjₘₐₓ) is 1.2° C. The initial temperature of sample No. 3 at the start of the test is 202.9° C., and the end of life is obtained when repeated 907,000 times.

In sample No. 4, the second coefficient of linear thermal expansion ρ2 of the buffer plate is less than the first coefficient of linear thermal expansion ρ1 of the semiconductor substrate, and the value defined by “ρ2−ρ1” is −1.9×10⁻⁶/° C. The increase in the maximum junction temperature (Tjₘₐₓ) is 1.2° C. The initial temperature of sample No. 4 at the start of the test is 212.6° C., and the end of life is obtained when repeated 472,000 times.

In sample No. 5, the second coefficient of linear thermal expansion ρ2 of the buffer plate is less than the first coefficient of linear thermal expansion ρ1 of the semiconductor substrate, and the value defined by “ρ2−ρ1” is −1.0×10⁻⁶/° C. The increase in the maximum junction temperature (Tjₘₐₓ) is 3.1° C. The initial temperature of sample No. 5 at the start of the test is 229.3° C., and the end of life is obtained when repeated 425,000 times.

In sample No. 5, the second coefficient of linear thermal expansion ρ2 of the buffer plate is less than the first coefficient of linear thermal expansion ρ1 of the substrate, and the thickness of the buffer plate is within a preferable range (greater than or equal to 0.05 mm and less than or equal to 0.25 mm). In this case, although the initial temperature (229.3° C.) of sample No. 5 is higher than those of the other samples, the increase in the temperature obtained when repeated 200,000 times to 300,000 times can be reduced, and a long life can be obtained.

In sample No. 6, the second coefficient of linear thermal expansion ρ2 of the buffer plate is less than the first coefficient of linear thermal expansion ρ1 of the semiconductor substrate, and the value defined by “ρ2−ρ1” is −2.8×10⁻⁶/° C. The increase in the maximum junction temperature (Tjₘₐₓ) is 2.7° C. The initial temperature of sample No. 6 at the start of the test is 205.1° C., and the end of life is obtained when repeated 558,000 times.

In sample No. 7, the second coefficient of linear thermal expansion ρ2 of the buffer plate is less than the first coefficient of linear thermal expansion ρ1 of the semiconductor substrate, and the value defined by “ρ2−ρ1” is −1.0×10⁻⁶/° C. The increase in the maximum junction temperature (Tjₘₐₓ) is 6.5° C. The initial temperature of sample No. 7 at the start of the test is 208.3° C., and the end of life is obtained when repeated 330,000 times.

In sample No. 7, the second coefficient of linear thermal expansion ρ2 of the buffer plate is less than the first coefficient of linear thermal expansion ρ1 of the substrate, but the thickness of the buffer plate is greater than an upper limit of the preferable range (greater than or equal to 0.05 mm and less than or equal to 0.25 mm). In this case, it is considered that heat dissipation is reduced due to increased heat and reduced heat transfer, caused by the increased electrical resistance, and that the resulting life is shortened as compared with sample No. 1.

In sample No. 8, the second coefficient of linear thermal expansion ρ2 of the buffer plate is less than the first coefficient of linear thermal expansion ρ1 of the semiconductor substrate, and the value defined by “ρ2−ρ1” is −1.9×10⁻⁶/° C. The increase in the maximum junction temperature (Tjₘₐₓ) is 7.5° C. The initial temperature of sample No. 8 at the start of the test is 202.8° C., and the end of life is obtained when repeated 325,000 times. It is considered that the life is shorter than that of sample No.

1 for the same reasons as described in sample No. 7. In sample No. 9, the second coefficient of linear thermal expansion ρ2 of the buffer plate is less than the first coefficient of linear thermal expansion ρ1 of the semiconductor substrate, and the value defined by “ρ2−ρ1” is −1.0×10⁻⁶/° C. The increase in the maximum junction temperature (Tjₘₐₓ) is 8.8° C. The initial temperature of sample No. 9 at the start of the test is 201.2° C., and the end of life is obtained when repeated 309,000 times. It is considered that the life is shorter than that of sample No. 1 for the same reasons as described in sample Nos. 7 and 8.

In sample No. 10, the second coefficient of linear thermal expansion ρ2 of the buffer plate is less than the first coefficient of linear thermal expansion ρ1 of the semiconductor substrate, and the value defined by “ρ2−ρ1” is −1.9×10⁻⁶/° C. The initial temperature of sample No. 10 at the start of the test is 210.3° C. In sample No. 10, the end of life is obtained before the number of repetitions reaches 200,000. When the inside of the sample No. 10 was observed, there was a crack in the diode.

In sample No. 10, the second coefficient of linear thermal expansion ρ2 of the buffer plate is less than the first coefficient of linear thermal expansion ρ1 of the substrate, but the thickness of the buffer plate is greater than the upper limit of the preferable range (greater than or equal to 0.05 mm and less than or equal to 0.25 mm), and also, the thickness of the buffer plate is greater than those of the other samples. In particular, the buffer plate is thicker than the diode (0.35 mm). In this case, it is presumed that the silicon carbide substrate of the diode could not withstand the stress from the buffer plate. In sample No. 11, the second coefficient of linear thermal expansion ρ2 of the buffer plate is less than the first coefficient of linear thermal expansion ρ1 of the semiconductor substrate, and the value defined by “ρ2−ρ1” is −1.9×10⁻⁶/° C. The increase in the maximum junction temperature (Tjₘₐₓ) is 2.3° C. The initial temperature of sample No. 11 at the start of the test is 206.8° C. The end of life is obtained when repeated 400,000 times or more.

As described above, in samples No. 2 to No. 6 in each of which the second coefficient of linear thermal expansion ρ2 of the buffer plate is less than the first coefficient of linear thermal expansion ρ1, and also, the thickness of the buffer plate is in the range of 0.05 mm to 0.25 mm, a lower increase in the maximum junction temperature (Tjₘₐₓ) is obtained when the number of repetitions is 200,000 to 300,000. This indicates that deterioration of the aluminum layer included in the anode electrode is suppressed. This is presumably because when the thickness of the buffer plate is in the range of 0.05 mm to 0.25 mm, an increase in the resistance and a decrease in heat dissipation can be suppressed.

As summarized in Table 1, from a systematic consideration and analysis by the inventors of this application, it has been found that when a semiconductor device having a lower increase in the maximum junction temperature (Tjₘₐₓ) obtained in a case where the number of repetitions is 200,000 to 300,000 is used, the finally obtained end of life (test life at a timing at which ΔTj increases by 20%) can be extended, and also, deterioration caused after the start of the test can be reduced, thereby ensuring a long time period in which very gradual deterioration is caused.

It is also understood from Table 1 that an operation test is performed at a temperature of 200° C. or higher in all of samples No. 1 to No. 11. It is found that in each of samples No. 2 to No. 6 and No. 11 in which a lower increase in the maximum junction temperature (Tjₘₐₓ) is obtained in a case where the number of repetitions is 200,000 to 300,000, a long life when repeated 400,000 times or more, which greatly exceed 300,000 times, is obtained. On the other hand, in sample No. 1 in which the second coefficient of linear thermal expansion ρ2 of the buffer plate is greater than the first coefficient of linear thermal expansion ρ1, a given number of repetitions, which results in the end of life, is less than 400,000.

Further, in the present disclosure, when a temperature increase ΔT1 from the initial temperature to the maximum junction temperature (Tjₘₐₓ), which is obtained at a timing at which the number of repetitions is 200,000 and, a given number of repetitions obtained at a timing at which ΔTj increases by 5% from the initial temperature are used as indexes, it is found that not only the life can be extended but also deterioration caused from an initial stage can be suppressed within a long time period.

Here, the result of the power cycling test is analyzed based on the ratio R of a given number of repetitions at a timing at which ΔTj increases by 5%, to a given number of repetitions at a timing at which the end of life is obtained.

It is understood that when a given number of repetitions at the timing at which ΔTj increases by 20% and a given number of repetitions at the timing at which ΔTj increases by 5% are close to each other, that is, when the ratio R is high, a state in which deterioration is reduced from an initial stage is maintained for a long time period, and that the temperature finally increases at a timing at which the life is nearly ended. This indicates that characteristics are stable from the initial stage to a timing obtained immediately before the end of life. In contrast, when the ratio R is low, deterioration is likely to be further caused from the initial stage, and the characteristics vary with the progress of deterioration.

For example, in samples No. 1 and No. 7 to No. 9, it is confirmed that an increase ΔT1 in the temperature from the initial stage is high, and deterioration that finally leads to failure is caused at an early stage. On the other hand, in samples No. 2 to No. 6 and No. 11, the increase in the temperature obtained when repeated 200,000 times to 300,000 times is low, and a long time period during which initial deterioration is suppressed can be maintained. That is, it is found that in samples No. 2 to No. 6 and No. 11, reliability that has not been provided in the related art can be maintained and secured. It is confirmed that such a situation also corresponds to the increase ΔT1 in the temperature.

As described above, when (1) the life, (2) the increase ΔT1 in the temperature, and (3) the number of repetitions at the timing at which ΔTj increases by 5% from an initial temperature are used as indexes, it is found that in samples No. 1 and No. 7 to No. 9, the increase ΔT1 in the temperature from the initial stage is high, that deterioration leading to failure finally is caused at an early stage, and that the life is finally short. On the other hand, in samples No. 2 to No. 6 and No. 11, it is found that the increase in the temperature obtained when repeated 200,000 times to 300,000 times is low, that deterioration is sufficiently reduced for a certain time period from the initial stage, that characteristics obtained at a timing that is very close to the initial stage can be maintained until immediately before the failure, and that the end of life can be extended. In this case, by using a semiconductor device using each of samples No. 2 to No. 6 and No. 11, a system with higher reliability for in-vehicle use, industrial use, or the like can be constructed, and the system can be used as a final product.

Next, a preferable change in the coefficient of linear thermal expansion of the buffer plate when a given temperature of the semiconductor device according to the embodiment of the present disclosure is increased and decreased once will be described.

In a test, the buffer plate is held at 25° C. for 30 minutes, then the temperature of the buffer plate is increased from 25° C. to 250° C., subsequently held at 250° C. for 30 minutes, and finally the temperature is decreased from 250° C. to 25° C. After the temperature is maintained at 25° C. for 30 minutes, a cycle in which the temperature increases and then decreases is repeated, and subsequently, the coefficient of linear thermal expansion of the buffer plate is continuously measured in the range of temperatures described above. A maximum value for a value defined by “ρ5−ρ4”, which is obtained in a case where the same temperature within the range of 25° C. to 250° C. is used to obtain a coefficient of linear thermal expansion (fifth coefficient of linear thermal expansion ρ5) during a temperature increase and a coefficient of linear thermal expansion (fourth coefficient of linear thermal expansion ρ4) during a temperature decrease is calculated.

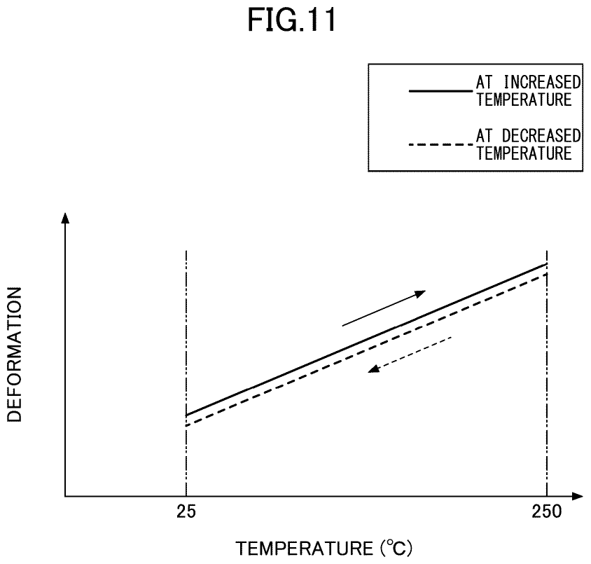

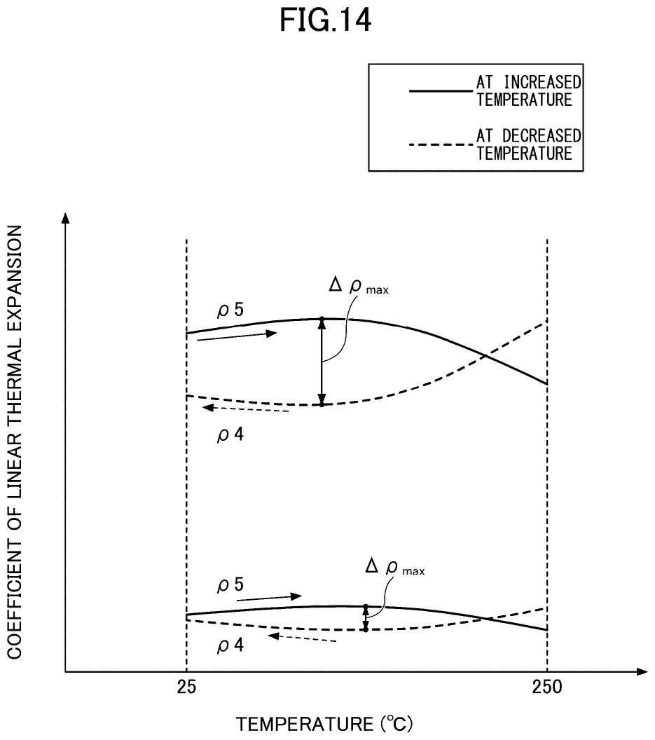

The significance of the value defined by “ρ5−ρ4” will be described below. FIGS. 11 to 13 are schematic views showing the change in deformation due to a temperature change. FIG. 14 is a diagram showing the change in the coefficient of liner thermal coefficient due to the temperature change.

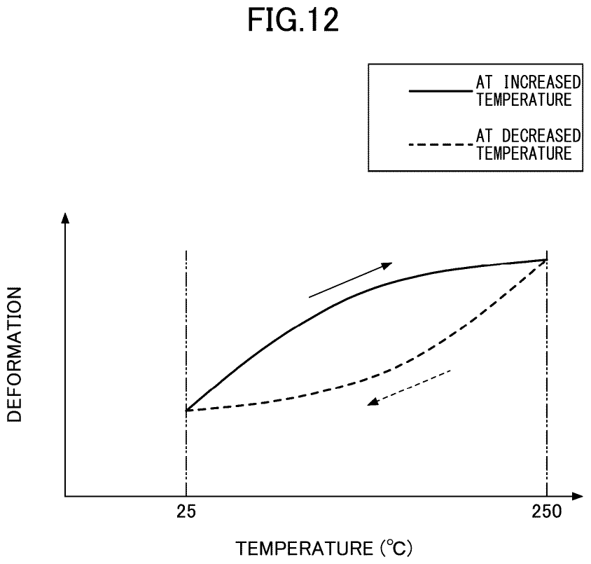

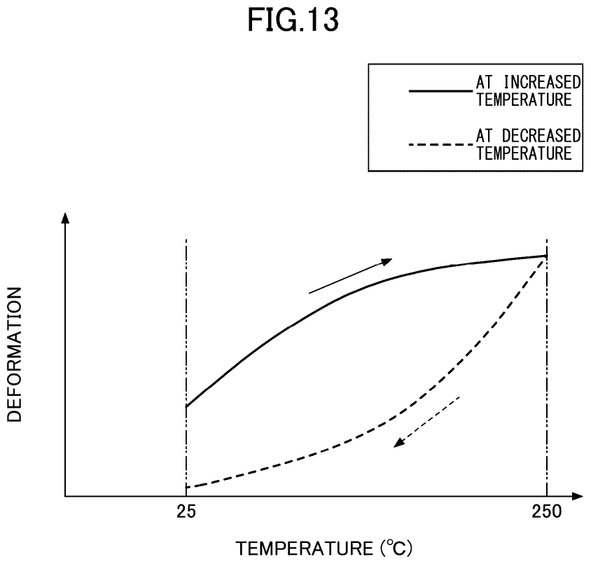

As shown in FIG. 11, it is also considered that the coefficients of linear thermal expansion at an increased temperature and at a decreased temperature are the same. However, as shown in FIG. 12, when the temperature increases from room temperature (25° C.), a difference appears between the fifth coefficient of linear thermal expansion ρ5 at the increased temperature and the fourth coefficient of linear thermal expansion ρ4 at the decreased temperature. In such a case, the semiconductor device may deteriorate within the range of operating temperatures of the semiconductor device, for example, within the temperature range of 25° C. to 250° C. Further, as shown in FIG. 13, the entire semiconductor device does not return to its original shape after one cycle of a temperature increase and a temperature decrease, and in a subsequent cycle, deformation may be further caused from a deformed state as a starting point. This is the cause of accelerated deterioration, which is referred to as “progressive deformation.”

Here, as shown in FIG. 14, when a semiconductor device having temperature characteristics 11 in which a maximum value Δμₘₐₓ for the value defined by “ρ5−ρ4” at any temperature in the range of from 25° C. to 250° C. is small is compared with a semiconductor device having temperature characteristics 12 in which the maximum value Δμₘₐₓ for the value defined by “ρ5-04” at any temperature in the range of from 25° C. to 250° C. is great, the semiconductor device having the temperature characteristics 11 is less likely to deteriorate.

In the semiconductor device according to the embodiment of the present disclosure, the maximum value Δμₘₐₓ for the value defined by “ρ5−ρ4” at any temperature in the range of from 25° C. to 250° C. is preferably 1.5×10⁻⁶/° C. or less, more preferably 1.3×10⁻⁶/° C. or less, and still more preferably 1.1×10⁻⁶/° C. or less. As the maximum value Δμₘₐₓ for the value defined by “ρ5−ρ4” is smaller, the coefficient of linear thermal expansion of the buffer plate is more likely to be stable, and internal fracture of the aluminum layer included in the source electrode is more likely to be suppressed even when a temperature history of a temperature increase and a temperature decrease is applied.

When the ratio of “a first copper layer:an iron-nickel alloy layer:and a second copper layer”=“33%:33%:33%” is expressed in percentage of the thicknesses, a maximum value for the value defined by “ρ5−ρ4” is 3.8×10⁻⁶/° C.

When the ratio of “the first copper layer:the iron-nickel alloy layer:the second copper layer”=“20%:60%:20%” is expressed in percentage of the thicknesses, the maximum value for the value defined by “ρ5−ρ4” is 1.9×10⁻⁶/° C.

In contrast, when the ratio of “the first copper layer:the iron-nickel alloy layer:the second copper layer”=“14%:72%:14%” is expressed in percentage of the thicknesses, the maximum value for the value defined by “ρ5−ρ4” is 1.5×10⁻⁶/° C. When the ratio of “the first copper layer:the iron-nickel alloy layer:the second copper layer”=“10%:80%:10%” is expressed in percentage of the thicknesses, the maximum value for the value defined by “ρ5−ρ4” is 1.3×10⁻⁶/° C. When the ratio of “the first copper layer:the iron-nickel alloy layer:the second copper layer”=“5%:90%:5%” is expressed in percentage of the thicknesses, the maximum value for the value defined by “ρ5−ρ4” is 1.1×10⁻⁶/° C. When the buffer plate is made of invar, the maximum value for the value defined by “ρ5−ρ4” is 0.7×10⁻⁶/° C.

The deformation of the buffer plate can be observed with high accuracy, by using a digital image correlation (DIC) method that uses an optical microscope or an electron microscope.

In the present disclosure, an aluminum alloy layer may be used instead of the aluminum layer. The material used for the bonding material is not limiting. For example, the bonding material may be formed of a sintered body of copper, silver, nickel, or an intermetallic compound containing copper and tin. The sintered body of the intermetallic compound containing copper and tin is obtained by, for example, transient liquid phase sintering.

In the present disclosure, the semiconductor chip is preferably a silicon carbide chip. The silicon carbide chip has excellent high-temperature resistance and is unlikely to fail even when used at high temperatures. Also, the silicon carbide chip has greater mechanical characteristics. Further, internal fracture of the main electrode containing aluminum is suppressed, and thus the semiconductor device as a whole can easily have an excellent lifetime even at high temperatures.

Although the embodiments have been described in detail, these embodiments are not limited to one or more specific embodiments. Various modifications and changes can be made within the scope described in the claims.

### DESCRIPTION OF SYMBOLS

1, 2: semiconductor device
11, 12: temperature characteristic
101, 102, 103: terminal
110: substrate
111: first conductive pattern
112: second conductive pattern
113: third conductive pattern
114: fourth conductive pattern
115: conductive layer
119: insulating substrate
120: heat sink
131, 132, 133, 134, 135: bonding material
161, 162, 163, 164, 165, 166: wire
190: case
191, 192: sidewall
193, 194: end wall
200: transistor (semiconductor chip)
210: silicon carbide substrate (semiconductor substrate)
210A 210B: main surface
231: gate electrode
232: source electrode (main electrode)
233: drain electrode
300: diode (semiconductor chip)
310: silicon carbide substrate (semiconductor substrate)
310A 310B: main surface
332: anode electrode (main electrode)
332A: aluminum layer
332B: plating layer
333: cathode electrode
400: buffer plate
410: first copper layer
420: iron-nickel alloy layer
430: second copper layer
500: buffer plate
510: first copper layer
520: iron-nickel alloy layer
530: second copper layer
531: crystal grain
630: bonding material
631: first region
632: second region
730: bonding material
731: gap

1. A semiconductor device comprising:
a semiconductor chip including a semiconductor substrate and a main electrode provided on the semiconductor substrate, the main electrode including an aluminum or aluminum alloy layer;
a buffer plate; and
a bonding material provided between the main electrode and the buffer plate,
wherein each of a first coefficient of linear thermal expansion of the semiconductor substrate and a second coefficient of linear thermal expansion of the buffer plate is less than a third coefficient of linear thermal expansion of the main electrode, and
wherein the second coefficient of linear thermal expansion is less than the first coefficient of linear thermal expansion.

2. The semiconductor device according to claim 1, wherein the buffer plate has a thickness of greater than or equal to 0.05 mm and less than or equal to 0.25 mm, and
wherein when the first coefficient of linear thermal expansion is expressed by ρ1 and the second coefficient of linear thermal expansion is expressed by ρ2, a value defined by “ρ2−ρ1” is greater than or equal to −2.8×10⁻⁶/° C. and less than or equal to −0.1×10⁻⁶/° C.

3. The semiconductor device according to claim 1, wherein the buffer plate has a thickness of greater than or equal to 0.05 mm and less than or equal to 0.25 mm, and
wherein when the first coefficient of linear thermal expansion is expressed by ρ1 and the second coefficient of linear thermal expansion is expressed by ρ2, a value defined by “ρ2−ρ1” is −2.8×10⁻⁶/° C.

4. The semiconductor device according to claim 1, wherein the buffer plate has a thickness of greater than or equal to 0.10 mm and less than or equal to 0.20 mm, and
wherein when the first coefficient of linear thermal expansion is expressed by ρ1 and the second coefficient of linear thermal expansion is expressed by ρ2, a value defined by “ρ2−ρ1” is greater than or equal to −2.0×10⁻⁶/° C. and less than or equal to −1.0×10⁻⁶/° C.

5. The semiconductor device according to claim 1, wherein a thickness of the buffer plate is less than a thickness of the semiconductor chip.

6. The semiconductor device according to claim 1, wherein the buffer plate includes a laminated material or an iron-nickel alloy material, and
wherein the laminated material includes
a first copper layer in contact with the bonding material,
an iron-nickel alloy layer provided on the first copper layer, and
a second copper layer provided on the iron-nickel alloy layer.

7. The semiconductor device according to claim 6, wherein the first copper layer and the second copper layer have a same thickness, and
wherein a thickness of the iron-nickel alloy layer is 72/14 times or more the thickness of each of the first copper layer and the second copper layer.

8. The semiconductor device according to claim 1, further comprising:
a wire bonded to the buffer plate.

9. The semiconductor device according to claim 8, wherein the wire is a copper wire.

10. The semiconductor device according to claim 8, wherein a crystal grain extending from the wire toward the buffer plate is provided at an interface between the wire and the buffer plate.

11. The semiconductor device according to claim 1, wherein the buffer plate includes
a first copper layer in contact with the bonding material,
an iron-nickel alloy layer provided on the first copper layer, and
a second copper layer provided on the iron-nickel alloy layer,
wherein the semiconductor device further includes a wire bonded to the buffer plate,
wherein the wire is a copper wire, and
wherein a crystal grain extending from the wire toward the buffer plate is provided at an interface between the wire and the buffer plate.

12. The semiconductor device according to claim 11, wherein the crystal grain extends to the iron-nickel alloy layer.

13. The semiconductor device according to claim 11, wherein the first copper layer and the second copper layer have a same thickness, and
wherein a thickness of the iron-nickel alloy layer is 72/14 times or more the thickness of each of the first copper layer and the second copper layer.

14. The semiconductor device according to claim 8, wherein when viewed from a direction perpendicular to a main surface of the semiconductor substrate, the bonding material includes
a first region overlapping a portion of the buffer plate to which the wire is bonded, and
a second region around the first region, and
wherein a coefficient of linear thermal expansion of the first region is less than a coefficient of linear thermal expansion of the second region.

15. The semiconductor device according to claim 14, wherein the first region is formed of silicon carbide, silicon, silicon oxide, silicon nitride, an iron-nickel alloy, molybdenum, or tungsten, and
wherein the second region is formed of copper, silver, nickel, or a sintered body of an intermetallic compound containing copper and tin.

16. The semiconductor device according to claim 8, wherein when viewed from a direction perpendicular to a main surface of the semiconductor substrate, a gap is provided in a portion of the bonding material that overlaps with a portion of the buffer plate to which the wire is bonded.

17. The semiconductor device according to claim 1, wherein the main electrode includes a plating layer, and
wherein the plating layer is provided between the aluminum or aluminum alloy layer and the buffer plate.

18. The semiconductor device according to claim 1, wherein in a power cycling test in which a maximum junction temperature in each cycle for the semiconductor chip is set to 200° C. or higher, an increase in the maximum junction temperature is 5.0° C. or lower, in a case where the number of repetitions is 200,000 to 300,000.

19. The semiconductor device according to claim 1, wherein under a condition in which a temperature of the buffer plate increases from 25° C. to 250° C., subsequently an increased temperature decreases from 250° C. to 25° C., and a coefficient of linear thermal expansion of the buffer plate is continuously measure during increasing and decreasing of the temperature,
when a coefficient of linear thermal expansion of the buffer plate during the increasing of the temperature is expressed by ρ5 and a coefficient of linear thermal expansion of the buffer plate during the decreasing of the temperature is expressed by ρ4, a maximum value for a value that is defined by “ρ5−ρ4” and is derived by a same temperature in a range of from 25° C. to 250° C. is 1.5×10⁻⁶/° C. or less.

20. The semiconductor device according to claim 1, wherein the semiconductor chip is a silicon carbide chip.

21. The semiconductor device according to claim 16, wherein the gap of the bonding material is configured to reduce stress acting on the main electrode.
